(19) United States
(12) Patent Application Publication
(10) Pub. No.: US 2024/0339493 A1
(43) Pub. Date: Oct. 10, 2024

(54) LOW LEAKAGE CAPACITORS, AND RELATED STRUCTURES, METHODS, AND SYSTEMS

(71) Applicant: ASM IP Holding B.V., Almere (NL)

(72) Inventors: Alessandra Leonhardt, Sipoo (FI); Varun Sharma, Helsinki (FI); Vivek Koladi Mootheri, Leuven (BE); Leo Lukose, Leuven (BE); Andrea Illiberi, Leuven (BE); Jerome Innocent, Bristol (GB); Aditya Chauhan, Ottignies-Louvain-Ia-Neuve (BE)

(21) Appl. No.: 18/624,808

(22) Filed: Apr. 2, 2024

Related U.S. Application Data
(60) Provisional application No. 63/494,156, filed on Apr. 4, 2023.

(51) Int. Cl. H01L 29/06; H01L 21/02; H01L 29/778

(52) U.S. Cl. CPC H01L 29/0607; H01L 21/02362; H01L 28/75; H01L 29/7786

(57) ABSTRACT

Structures and related methods and systems for forming structures. The structures comprise a proximal contact, a distal contact, a high-k dielectric, and at least one of a proximal barrier and a distal barrier. In some embodiments, at least one of the proximal barrier and the distal barrier is constructed and arranged to inhibit Poole-Frenkel emission from the high-k dielectric when a first electric field is applied between the proximal contact and a distal contact in a first electric field direction.

### CROSS-REFERENCE TO RELATED APPLICATION(S)

This Application claims the benefit of U.S. Provisional Application 63/494,156 filed on Apr. 4, 2023, the entire contents of which are incorporated herein by reference.

### FIELD OF INVENTION

The present disclosure generally relates to the field of semiconductor processing methods and systems, and to the field integrated circuit manufacture. In particular, memory elements, components thereof, and methods and systems suitable for forming memory elements and programmable logic devices are disclosed herein.

### BACKGROUND OF THE DISCLOSURE

Next generation Metal-Insulator-Metal (MIM) capacitors for both logic and memory applications are strongly affected by leakage current. Reducing the leakage current becomes a critical aspect of being able to scale down the dimensions on the dielectric thus achieving high capacitance densities. Some strategies to reduce the leakage current are to employ high work function electrodes, add oxygen scavenging blocking layers or somehow reduce the trap density inside the dielectric. Each of those alternatives have their own drawbacks. Thus, there is a need for further strategies for reducing leakage in scaled MIM capacitors.

In addition, three-dimensional (3D) dynamic random access memory (DRAM) will eventually need capacitors comprising dielectric materials with dielectric constants (k) greater than 50, and conventional solutions don't reach those numbers, specially when taking the need for good C-V linearity in consideration. However, some materials with such high dielectric constants can suffer from high leakage currents. Thus, there is a need for improved metal-insulator-metal (MIM) capacitors having a high dielectric constant and low leakage.

### SUMMARY OF THE DISCLOSURE

Some aspects of the present disclosure relate to the use of a semiconductor, e.g. semiconducting oxide, e.g. a wide band gap semiconducting oxide such as nickel oxide, to act as a electron barrier to reduce leakage in MIM capacitors.

Described herein is a structure comprising a proximal contact, a proximal barrier, a high-k dielectric, and a distal contact; the proximal contact being adjacent to the proximal barrier; the proximal barrier being positioned between the proximal contact and the high-k dielectric, and the high-k dielectric being positioned between the proximal barrier and the distal contact; wherein the proximal barrier is constructed and arranged to inhibit Poole-Frenkel emission from the high-k dielectric when a first electric field is applied between the proximal contact and a distal contact in a first electric field direction.

In some embodiments, the structure further comprises a distal barrier, the distal barrier being positioned between the high-k dielectric and the distal contact, the distal barrier being constructed and arranged to inhibit Poole-Frenkel emission from the high-k dielectric when a second electric field is applied between the proximal contact and the distal contact in a second electric field direction, the second electric field direction being opposite to the first electric field direction.

In some embodiments, at least one of the distal barrier and the proximal barrier comprises a plurality of nanoparticles.

In some embodiments, the high-k dielectric has a high-k dielectric band gap, wherein the proximal barrier has a proximal barrier band gap, and optionally wherein the distal barrier has a distal barrier band gap.

In some embodiments, at least one of the proximal barrier band gap and the distal barrier band gap is smaller than the high-k dielectric band gap.

In some embodiments, the distal barrier band gap and the high-k dielectric band gap define a distal valence band offset, optionally wherein the proximal barrier band gap and the high-k dielectric band gap define a proximal valence band offset.

In some embodiments, at least on of the proximal valence band offset and the distal valence band offset are greater than 0.5 eV.

In some embodiments, the distal barrier band gap and the high-k dielectric band gap further define a distal conduction band offset, optionally wherein the proximal barrier band gap and the high-k dielectric band gap further define a proximal conduction band offset; and, wherein the distal valence band offset is bigger than the distal conduction band offset, and/or wherein the proximal valence band offset is bigger than the proximal conduction band offset.

In some embodiments, the distal barrier band gap and the high-k dielectric band gap define a distal conduction band offset, optionally wherein the proximal barrier band gap and the high-k dielectric band gap define a proximal conduction band offset.

In some embodiments, at least on of the proximal conduction band offset and the distal conduction band offset are greater than 0.5 eV.

In some embodiments, the distal barrier band gap and the high-k dielectric band gap further define a distal valence band offset, optionally wherein the proximal barrier band gap and the high-k dielectric band gap further define a proximal valence band offset; and, wherein the distal conduction band offset is bigger than the distal valence band offset, and/or wherein the proximal conduction band offset is bigger than the proximal valence band offset.

Further described herein is a method of forming a structure, the method comprising: providing a substrate to a reaction chamber, the substrate comprising a distal contact; forming a distal barrier on the distal contact; forming a high-k dielectric on the distal barrier; forming a proximal barrier on the high-k dielectric; and, forming a proximal contact on the proximal barrier. In some embodiments, the structure is a structure as described herein.

In some embodiments, at least one of the distal barrier and the proximal barrier comprises executing a cyclical deposition process, the cyclical deposition process comprising a plurality of deposition cycles, ones from the plurality of deposition cycles comprising a precursor pulse and a reactant pulse, the precursor pulse comprising contacting the substrate with a precursor, the reactant pulse comprising contacting the substrate with a reactant, subsequent pulses being optionally separated by purges.

In some embodiments, at least one of the distal barrier and the proximal barrier comprises one or more of nickel oxide, aluminum nitride, magnesium oxide, scandium oxide, lanthanum oxide, aluminum oxide, zirconium oxide, hafnium oxide, strontium titanium oxide, and titanium oxide.

In some embodiments, the high-k dielectric comprises hafnium, zirconium, and oxygen.

In some embodiments, at least one of the distal contact and the proximal contact comprises a transition metal nitride.

In some embodiments, at least one of the proximal barrier and the distal barrier does not substantially contribute to an equivalent oxide thickness of a capacitor formed by the high-k dielectric, the distal contact, the proximal contact, and one or more of the proximal barrier and the distal barrier.

Further described herein is a system comprising a reaction chamber, a precursor source, a reactant source, and a controller, wherein the system is constructed and arranged for executing a method as described herein.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1A-1B show structures according to embodiments of the present disclosure.

FIGS. 2A-2I show band diagrams of structures according to embodiments of the present disclosure.

FIGS. 3A-3C illustrate methods according to embodiments of the present disclosure.

FIG. 4 schematically shows a process flow of an embodiment of a method according to the present disclosure.

FIG. 5 shows experimental current-voltage characteristics of structures according to embodiments of the present disclosure.

FIG. 6 illustrates a system in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The term “deposition process” as used herein can refer to the introduction of precursors (and/or reactants) into a reaction chamber to deposit a layer over a substrate. “Cyclical deposition processes” are examples of “deposition processes”.

The term “cyclic deposition process” or “cyclical deposition process” can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

The term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, atomic layer epitaxy (ALE), molecular beam epitaxy (MBE), gas source MBE, organometallic MBE, and chemical beam epitaxy, when performed with alternating pulses of precursor(s)/reactive gas(es), and purge (e.g., inert carrier) gas(es). A pulse can comprise exposing a substrate to a precursor or reactant. This can be done, for example, by introducing a precursor or reactant to a reaction chamber in which the substrate is present. Additionally or alternatively, exposing the substrate to a precursor can comprise moving the substrate to a location in a substrate processing system in which the reactant or precursor is present.

Generally, for ALD processes, during each cycle, a precursor is introduced into a reaction chamber and is chemisorbed onto a deposition surface (e.g., a substrate surface that can include a previously deposited material from a previous ALD cycle or other material) and forming about a monolayer or sub-monolayer of material that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. The reactant can be capable of further reaction with the precursor. Purging steps can be utilized during one or more cycles, e.g., during each step of each cycle, to remove any excess precursor from the process chamber and/or remove any excess reactant and/or reaction byproducts from the reaction chamber.

As used herein, the term “pulse” may refer to a procedure in which a reactive precursor or reactant is provided to a reaction chamber, for example in between two purges, between a purge and another pulse, or between two pulses. It shall be understood that a pulse can be effected either in time or in space, or both. For example in the case of temporal pulses, a pulse step can be used e.g. in the temporal sequence of executing a purge that comprises providing a purge gas to a reaction chamber, a pulse in which a precursor is provided to the reaction chamber, and another purge that comprises providing a purge gas to the reaction chamber. In this case, the substrate on which a layer is deposited does not necessarily move during the purge-pulse-purge sequence. For example in the case of spatial pulses, a pulse step can take the following form: moving a substrate through a purge gas curtain to a pulse location where a precursor or reactant is continually supplied, and then moving the substrate through the same or another purge gas curtain again.

As used herein, the term “purge” may refer to a procedure in which an inert or substantially inert gas is provided to a reaction chamber in between two pulses of gasses that react with each other. For example, a purge, e.g. using a noble gas, may be provided between a precursor pulse and a reactant pulse, thus avoiding or at least minimizing gas phase interactions between the precursor and the reactant. It shall be understood that a purge can be effected either in time or in space, or both. For example in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example in the case of spatial purges, a purge step can take the following form: moving a substrate from a first location to which a first precursor is continually supplied, through a purge gas curtain, to a second location to which a second precursor is continually supplied.

As used herein, the term “comprising” indicates that certain features are included, but that it does not exclude the presence of other features, as long as they do not render the claim or embodiment unworkable. In some embodiments, the term “comprising” includes “consisting”. As used herein, the term “consisting” indicates that no further features are present in the apparatus/method/product apart from the ones following said term. When the term “consisting” is used referring to a chemical compound, it indicates that the chemical compound only contains the components which are listed.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

In one aspect, described herein are structures such as metal-insulator-metal capacitors comprising two contacts, at least one barrier, and a high-k dielectric. The barrier can comprise a low electron affinity material, such as a low electron affinity oxide or nitride, to act as a electron barrier to reduce leakage, particularly by Poole-Frenkel emission, in metal-insulator-metal capacitors. Further described herein are methods and systems for forming such structures.

In one embodiment, nickel (II) oxide (NiO) can be added at both top and bottom metal/oxide interfaces of a MIM capacitor to reduce the leakage current. NiO is a p-type semiconducting material with a wide band gap and Fermi level close to the valence band. These properties make this material an excellent candidate for alternative leakage current blocking layer, since it is expected to result in practically zero EOT increase and significant leakage reduction, especially at high bias voltages.

In one aspect, and without wishing to be bound to any particular theory or mode of operation, it is believed that suitable barrier materials include wide band gap materials with a very low electron affinity (e.g. less than 2.0 eV, such as 1.8 eV) between high-k dielectric and contact in a metal-insulator-metal capacitor. Such a barrier can act as an electron barrier.

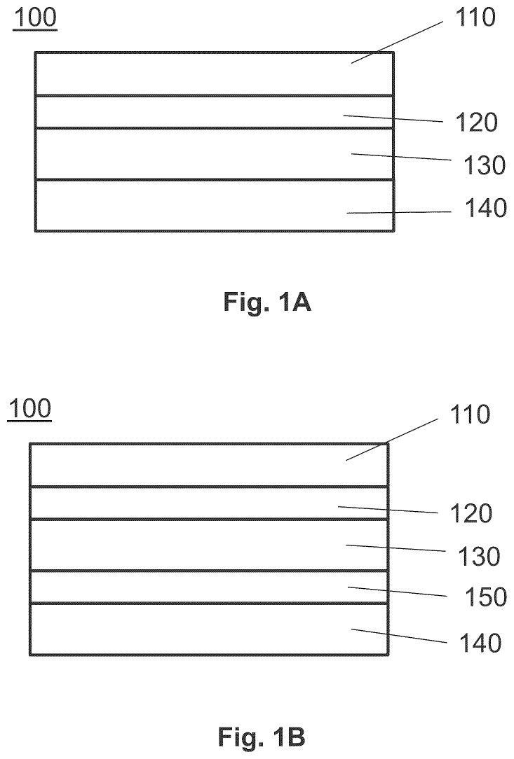

With reference to FIG. 1A, described herein is a structure 100 that comprises a proximal contact 110, a proximal barrier 120, a high-k dielectric 130, and a distal contact 140. The proximal contact 110 is adjacent to the proximal barrier 120. The proximal barrier 120 is positioned between the proximal contact 110 and the high-k dielectric 130. The high-k dielectric 130 is positioned between the proximal barrier 120 and the distal contact 140. The proximal barrier 120 can be constructed and arranged to inhibit Poole-Frenkel emission from the high-k dielectric 130 when a first electric field is applied between the proximal contact 110 and a distal contact 140 in a first electric field direction.

Referring to FIG. 1B, a structure 100 as described herein can further comprise a distal barrier 150. The distal barrier 150 can be positioned between the high-k dielectric 130 and the distal contact 140. The distal barrier 150 can be constructed and arranged to inhibit Poole-Frenkel emission from the high-k dielectric 130 when a second electric field is applied between the proximal contact 110 and the distal contact 140 in a second electric field direction, the second electric field direction being opposite to the first electric field direction.

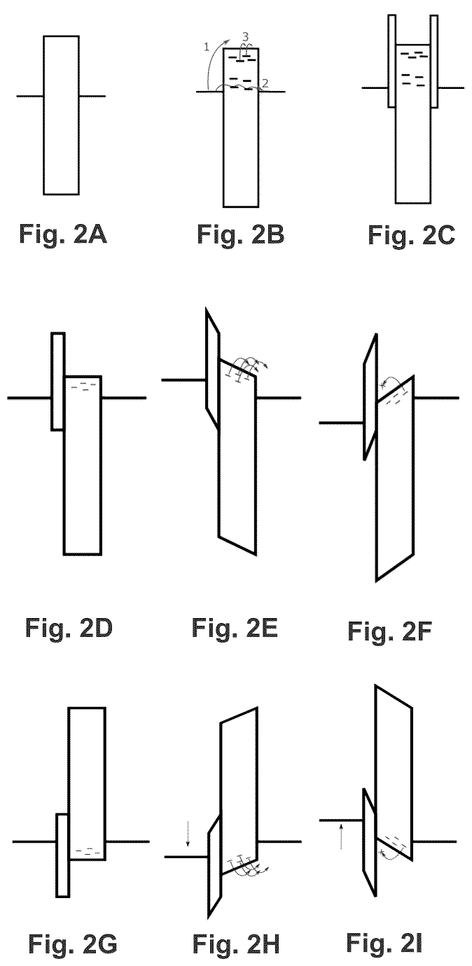

The operation of structures comprising at least one of a proximal barrier 120 and a distal barrier 150 is further explained with reference to the band diagrams shown in FIGS. 2A-2I.

In particular, FIG. 2A shows a band diagram of an idealized, defect-free dielectric sandwiched between two metallic contacts under zero bias conditions.

Most real dielectrics are not defect-free but contain defects. Such defects can facilitate current flow across dielectric barriers, which corresponds to undesirable leakage currents in metal-insulator-metal capacitors. FIG. 2B illustrates three different leakage mechanism: thermionic emission 1, direct tunneling 2, and Poole-Frenkel emission 3.

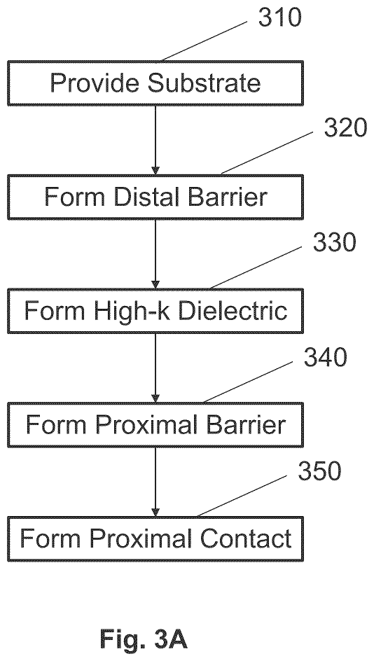

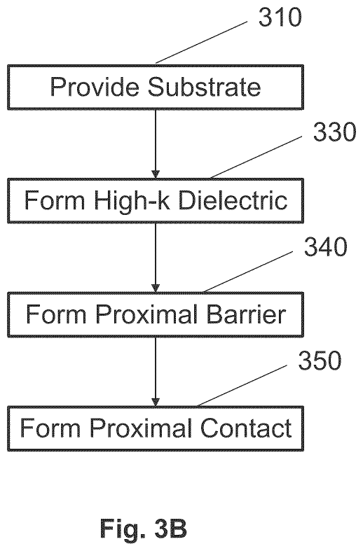

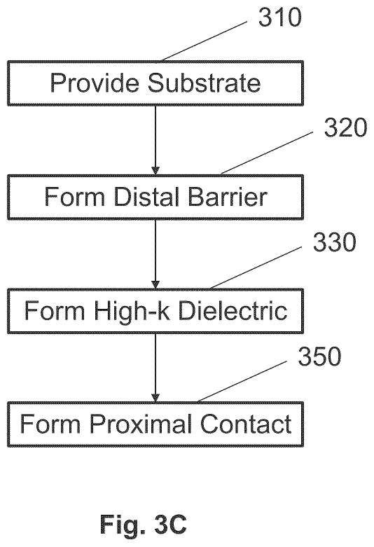

Poole-Frenkel emission is a trap-mediated leakage mechanism. In embodiments of the present disclosure, Poole-Frenkel emission can be suppressed by use of at least one of a proximal barrier and a distal barrier. FIG. 2C shows a band diagram of an embodiment of a structure in which a proximal barrier and a distal barrier are provided between a dielectric and a proximal contact and a distal contact, respectively. In the embodiment of FIG. 3C, the proximal and distal barriers are constituted of a p-type semiconductor with a relatively low electron affinity compared to the dielectric, such that the proximal and distal barriers create forbidden states at energy levels around and above the conduction band edge of the dielectric. Such a structure can suitably eliminate or reduce leakage currents created by Poole-Frenkel emission of electrons from shallow traps near the conduction band edge. Since the structure is symmetrical, the leakage current reduction occurs regardless of bias direction. This is particularly useful for use in metal-insulator-metal capacitors in which the energy gap between metal Fermi level and dielectric conduction band edge is smaller than the energy gap between metal Fermi level and dielectric valence band edge.

FIG. 2D shows the band diagram of an embodiment of a structure that comprises a proximal and a distal contact, a dielectric, and one barrier. For ease of reference, the barrier will be called a proximal barrier, but the case of a distal barrier is analogous. The dielectric comprises shallow traps near the conduction band edge. FIG. 2D shows the structure at zero bias. In the embodiment of FIG. 2D, the barrier is constituted of a p-type semiconductor with a relatively low electron affinity compared to the dielectric, such that barrier creates forbidden states at energy levels around and above the conduction band edge of the dielectric.

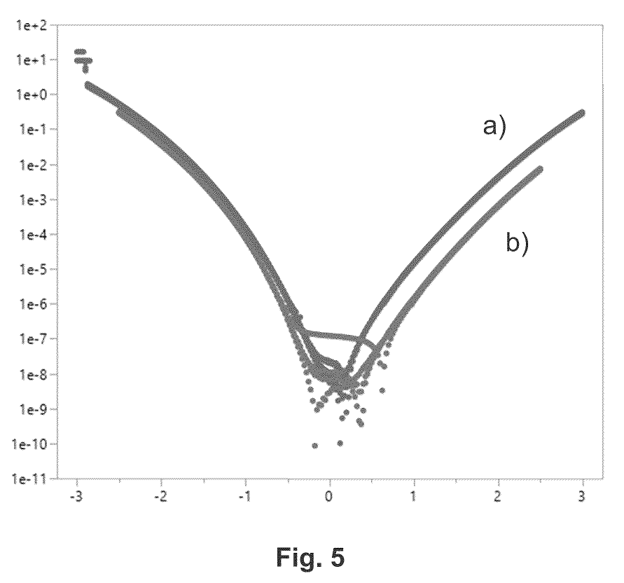

FIG. 2E shows a band diagram of the same structure as in FIG. 2D, but now under an applied bias. In particular, the proximal contact adjacent to the proximal barrier is negatively biased versus the distal contact. The resulting field causes electrons to flow from the proximal contact to the distal contact. Experiments (see FIG. 5) show that the proximal barrier has no or a minor effect on current flow in this case.

FIG. 2F shows a band diagram of the same structure as in FIG. 2D, but now under a different applied bias. In particular, the proximal contact adjacent to the proximal barrier is positively biased versus the distal contact. The resulting field causes electrons to flow from the distal contact to the proximal contact. Experiments (see FIG. 5) show that the proximal barrier reduces current flow in this case. Without wishing to be bound by any particular theory or mode of operation, it is believed that the reduced current flow is caused by a reduction in Poole-Frenkel emission.

FIG. 2G shows the band diagram of an embodiment of a structure that comprises a proximal and a distal contact, a dielectric, and one barrier. For case of reference, the barrier will be called a proximal barrier, but the case of a distal barrier is analogous. The dielectric comprises shallow traps near the valence band edge. FIG. 2G shows the structure at zero bias. In the embodiment of FIG. 2G, the barrier is constituted of an n-type semiconductor with a relatively high electron affinity compared to the dielectric, such that the barrier creates forbidden states at energy levels around and above the valence band edge of the dielectric.

FIG. 2H shows a band diagram of the same structure as in FIG. 2G, but now under an applied bias. In particular, the proximal contact adjacent to the proximal barrier is negatively biased versus the distal contact. The resulting field causes holes to flow from the proximal contact to the distal contact. It is believed that the proximal barrier has no or a minor effect on current flow in this case.

FIG. 2I shows a band diagram of the same structure as in FIG. 2G, but now under a different applied bias. In particular, the proximal contact adjacent to the proximal barrier is negatively biased versus the distal contact. The resulting field causes holes to flow from the distal contact to the proximal contact. It is believed that the proximal barrier reduces current flow in this case. Without wishing to be bound by any particular theory or mode of operation, it is believed that the reduced current flow is caused by a reduction in Poole-Frenkel emission.

Thus, in some embodiments, described herein are metal-insulator-metal capacitors that comprise an asymmetric barrier, i.e. in which current flow in one direction is restricted more than in the reverse direction.

In some embodiments, at least one of the distal barrier 150 and the proximal barrier 120 comprises a plurality of nanoparticles. In some embodiments, the distal barrier 150 comprises a plurality of nanoparticles. In some embodiments, the proximal barrier 120 comprises a plurality of nanoparticles. In some embodiments, the proximal barrier 120 and the distal barrier 150 comprise a plurality of nanoparticles.

The high-k dielectric has a high-k dielectric band gap. The distal barrier has a distal barrier band gap. The proximal barrier has a proximal barrier band gap.

In some embodiments, at least one of the proximal barrier band gap and the distal barrier band gap is smaller than the high-k dielectric band gap.

In some embodiments, the distal barrier band gap and the high-k dielectric band gap define a distal valence band offset. Optionally, the proximal barrier band gap and the high-k dielectric band gap define a proximal valence band offset.

In some embodiments, at least on of the proximal valence band offset and the distal valence band offset are greater than 0.5 eV. In some embodiments, the proximal valence band offset is greater than 0.5 eV. In some embodiments, the distal valence band offset is greater than 0.5 eV. In some embodiments, the proximal and distal valence band offsets are greater than 0.5 eV.

In some embodiments, the distal barrier band gap and the high-k dielectric band gap further define a distal conduction band offset. In some embodiments, the proximal barrier band gap and the high-k dielectric band gap define a proximal conduction band offset. In some embodiments, the distal valence band offset is bigger than the distal conduction band offset. In some embodiments, the proximal valence band offset is bigger than the proximal conduction band offset. In some embodiments, the distal valence band offset is bigger than the distal conduction band offset, and the proximal valence band offset is bigger than the proximal conduction band offset.

In some embodiments, the distal barrier band gap and the high-k dielectric band gap define a distal conduction band offset. In some embodiments, the proximal barrier band gap and the high-k dielectric band gap define a proximal conduction band offset.

In some embodiments, at least one of the proximal conduction band offset and the distal conduction band offset are greater than 0.5 eV.

In some embodiments, distal barrier band gap and the high-k dielectric band gap further define a distal valence band offset. In some embodiments, the proximal barrier band gap and the high-k dielectric band gap further define a proximal valence band offset. In some embodiments, the distal conduction band offset is bigger than the distal valence band offset. In some embodiments, the proximal conduction band offset is bigger than the proximal valence band offset. In some embodiments, the distal conduction band offset is bigger than the distal valence band offset and the proximal conduction band offset is bigger than the proximal valence band offset.

In some embodiments, the band gap of at least one of the distal barrier and the proximal barrier is smaller than the band gap of the high-k dielectric. In such a case, the barrier can provide either a hole barrier, or an electron barrier, but not both. For example, this can be the case when the high-k dielectric comprises hafnium zirconium oxide and when at least one of the proximal barrier and the distal barrier comprises nickel oxide.

In some embodiments, the band gap of at least one of the distal barrier and the proximal barrier is bigger than the band gap of the high-k dielectric. In such a case, the barrier can provide both a hole barrier and an electron barrier. For example, this can be the case when the high-k dielectric comprises hafnium zirconium oxide and when at least one of the proximal barrier and the distal barrier comprises at least one of magnesium oxide and aluminum oxide.

In some embodiments, at least one of the proximal barrier and the distal barrier does not substantially contribute to an equivalent oxide thickness of a capacitor formed by the high-k dielectric, the distal contact, the proximal contact, and one or more of the proximal barrier and the distal barrier. This can be done, for example, by selecting a barrier with a relatively narrow band gap and a small thickness. In some embodiments, the barrier can comprise a plurality of nanoparticles or isolated islands. For example, a barrier comprising a sub-nanometer dusting of nickel oxide was found to have a negligible contribution to effective oxide thickness of capacitors comprising the following materials stack: titanium nitride distal electrode|nickel oxide distal barrier|hafnium zirconium oxide high-k dielectric|nickel oxide proximal barrier|titanium nitride proximal electrode.

In some embodiments, the high-k material comprises a dielectric selected from the list consisting of hafnium oxide (HfO₂), zirconium oxide (ZrO₂), hafnium zirconium oxide (HfZrO₂), hafnium zirconium oxide (HfZrO₂, HfZrO₄, HfₓZr₁₋ₓO₂), and strontium titanate (SrTiO₃). It shall be understood that Hf₁₋ₓZrₓO₂ represents a non-stoichiometric oxide comprising hafnium and zirconium, and that x is a real number, e.g. a positive real number. In some embodiments, the high-k dielectric comprises a non-stoichiometric oxide such as a non-stoichiometric hafnium zirconium oxide comprising hafnium, zirconium, and oxygen.

Suitable contacts include metals such as molybdenum, metallic compounds such as titanium nitride, degenerately doped semiconductors such as indium tin oxide or phosphorous-or boron-doped silicon.

In some embodiments, the contacts include a semiconductor, in which case structures according to the present disclosure can be described as semiconductor-insulator-semiconductor structures.

In some embodiments, at least one of the distal contact and the proximal contact comprises a material selected from the list consisting of titanium nitride (TiN), cobalt (Co), molybdenum (Mo), ruthenium (Ru), and tungsten (W).

In some embodiments, at least one of the distal barrier and the proximal barrier comprises a material selected from the list consisting of nickel oxide, aluminum nitride, magnesium oxide, scandium oxide, lanthanum oxide, aluminum oxide, zirconium oxide, hafnium oxide, strontium titanium oxide, and titanium oxide. In some embodiments the proximal barrier comprises a material selected from the list consisting of nickel oxide, aluminum nitride, magnesium oxide, scandium oxide, lanthanum oxide, aluminum oxide, zirconium oxide, hafnium oxide, strontium titanium oxide, and titanium oxide. In some embodiments the distal barrier comprises a material selected from the list consisting of nickel oxide, aluminum nitride, magnesium oxide, scandium oxide, lanthanum oxide, aluminum oxide, zirconium oxide, hafnium oxide, strontium titanium oxide, and titanium oxide. In some embodiments the proximal and the distal barrier comprises a material selected from the list consisting of nickel oxide, aluminum nitride, magnesium oxide, scandium oxide, lanthanum oxide, aluminum oxide, zirconium oxide, hafnium oxide, strontium titanium oxide, and titanium oxide.

For example, nickel(II) oxide (NiO) is a p-type semiconducting material with a wide band gap, low electron affinity (1.8 eV), and a Fermi level close to the valence band. These properties make this material an excellent candidate as a leakage current blocking layer, e.g. proximal and/or distal barrier, since it can advantageously result in practically zero equivalent oxide thickness (EOT) increase and significant leakage reduction.

In some embodiments, at least one of the proximal barrier and the distal barrier is formed by means of a cyclical deposition process such as atomic layer deposition (ALD). Advantageously, ALD can yield very high-quality barriers.

In some embodiments, at least one of the proximal barrier and the distal barrier comprises an electron barrier. Suitable electron barriers include metal nitrides such as aluminum nitride (AlN) and metal oxides such as magnesium oxide (MgO), scandium oxide (Sc₂O₃), and nickel oxide (NiO).

In some embodiments, the high-k dielectric comprises a nickel oxide layer which can be doped with a rare earth clement such as scandium, yttrium, lanthanum, cerium, praseodymium, neodymium, samarium, europium, gadolinium, terbium, dysprosium, holmium, erbium, thulium, ytterbium, and lutetium. Suitably, nickel oxide can comprise a rare earth element in a concentration of at least 10⁻⁵ atomic percent to at most 10⁻⁴ atomic percent, or of at least 10⁻⁴ atomic percent to at most 10⁻³ atomic percent, or of at least 10⁻³ atomic percent to at most 10⁻² atomic percent, or of at least 10⁻² atomic percent to at most 10⁻¹ atomic percent, or of at least 10⁻¹ atomic percent to at most 1 atomic percent, or of at least 1 atomic percent to at most 10 atomic percent, or of at least 10 atomic percent to at most 20 atomic percent.

In some embodiments, the high-k dielectric can comprise additional metals apart from nickel and one or more rare earth elements. For example, the high-k dielectric can comprise a rare earth metal such as lanthanum and an alkaline earth metal such as magnesium in the case of LaSrNiO₄. For example, the high-k dielectric can comprise nickel and two rare earth metals, for example scandium and lanthanum in the case of ScLaNiO₄, samarium and lanthanum in the case of SmLaNiO₄, and samarium and neodymium in the case of SmNdNiO₄

In some embodiments, the nickel oxide layer doped with a rare earth element can comprises a rare earth nickelate. Rare earth nickelates include erbium nickelate (Er:NiO), yttrium nickelate (Y:NiO), gadolinium nickelate (Gd:NiO), and strontium lanthanum nickelate (Sr:LaNiO).

Advantageously, nickel oxide doped with a rare earth element can have a large dielectric constant (k) and a linear capacitance-voltage relation, and can be employed in three-dimensional dynamic random access memory (3D DRAM). This notwithstanding, nickel oxide doped with a rare earth element can have a relatively low band gap, which corresponds to high leakage currents in metal-insulator-metal capacitors that employ rare earth doped nickel oxide as a dielectric. Therefore, at least one of a proximal barrier and a distal barrier can be employed for reducing their leakage current of capacitors comprising an electrical insulator comprising nickel oxide doped with a rare earth element.

In some embodiments, at least one of the proximal electrode and the distal electrode comprises titanium nitride when the high-k dielectric comprises nickel oxide doped with a rare earth element.

Advantageously, at least one of the proximal barrier and the distal barrier comprises a hole blocking layer when the high-k dielectric comprises nickel oxide doped with a rare earth element. Suitable hole blocking layers include magnesium oxide (MgO) which has a large band gap and a relatively low dielectric constant, and hafnium zirconium oxide (HZO) which has a medium band gap and a high dielectric constant. Other suitable hole blocking layers include aluminum oxide.

In some embodiments, at least one of the proximal barrier and the distal barrier comprises a plurality of nanoparticles. Indeed, in some embodiments, only a sub-nm dusting of each of those materials is needed to act as a hole barrier.

With reference to FIG. 3A, further described herein is a method 300 of forming a structure, such as a structure as described herein. The structure can be, or can comprise, a structure as described herein. The method comprises a step 310 of providing a substrate to a reaction chamber. The substrate comprises a distal contact. The method further comprises a step 320 of forming a distal barrier on the distal contact. The method further comprises a step 330 of forming a high-k dielectric on the distal barrier. The method further comprises a step 340 of forming a proximal barrier on the high-k dielectric. The method further comprises a step 350 of forming a proximal contact on the proximal barrier.

In some embodiments, forming the distal barrier is omitted. Such an embodiment of a method as described herein is shown in FIG. 3B In particular, the embodiment of FIG. 3B comprises a step 310 of providing a substrate to a reaction chamber. The substrate comprises a distal contact. The method further comprises a step 330 of forming a high-k dielectric on the distal contact. The method further comprises a step 340 of forming a proximal barrier on the high-k dielectric. The method further comprises a step 350 of forming a proximal contact on the proximal barrier.

In some embodiments, forming the proximal barrier is omitted. Such an embodiment of a method as described herein is shown in FIG. 3C. In particular, the embodiment of FIG. 3C comprises a step 310 of providing a substrate to a reaction chamber. The substrate comprises a distal contact. The method further comprises a step 320 of forming a distal barrier on the distal contact. The method further comprises a step 330 of forming a high-k dielectric on the distal barrier. The method further comprises a step 350 of forming a proximal contact on the high-k dielectric.

In some embodiments, at least one of the distal barrier and the proximal barrier comprises executing a cyclical deposition process such as atomic layer deposition (ALD). The cyclical deposition process can comprise a plurality of deposition cycles. Ones from the plurality of deposition cycles can comprise a precursor pulse and a reactant pulse. The precursor pulse can comprise contacting the substrate with a precursor. The reactant pulse comprises contacting the substrate with a reactant. Subsequent pulses are optionally separated by purges.

In some embodiments, the reactant pulse is thermal, i.e. it does not comprise generating a plasma.

In some embodiments, the reactant pulse comprises generating a plasma. Suitable plasmas include direct plasmas, indirect plasmas, and remote plasmas. Plasmas can be generated using various means, such as capacitively-coupled radio frequency (RF) power, inductively-coupled RF power, and microwave power. Thus, a reactant pulse can comprise exposing the substrate to plasma species such as ions and radicals. For examples, the plasma species can be generated from a plasma comprising one or more of a noble gas such as argon or helium, nitrogen, oxygen, and hydrogen.

For example, for a nickel oxide barrier, the precursor can comprise a nickel amidinate such as nickel bis(N,N′-ditertialbutylacetamidinate). Other suitable nickel precursors include nickel beta diketonates such as nickel(II) acetylacetonate, nickel amidinates such as nickel bis(N,N′-ditertialbutylacetamidinate), nickel pi complexes such as Ni(RCp)₂ where Cp is cyclopentadienyl and R is alkyl such as methyl or ethyl, nickel precursors comprising one or more dialkylaminoalkoxide ligands such as Ni(dmamp)₂ where dmamp is 1-dimethylamino-2-methyl-2-propanolate, nickel cyclopentadienyls such as Ni(Cp)₂ where Cp is cyclopentadienyl, nickel diazadienyl complexes such as Ni(tBu₂DAD)₂ where tBu₂DAD is 1,4-di-tert-butyl-1,4-diazabutadienyl-bis(tert-butylimido). For a nickel oxide barrier, the reactant can comprise an oxygen reactant such as H₂O₂, H₂O, O₂ or O₃.

For example, for an aluminum oxide barrier the precursor can comprise an aluminum alkyl such as trimethylaluminum, a heteroleptic aluminum precursor comprising one or more alkyl ligands and one or more alkoxy ligands such as dimethyl aluminium isopropoxide, or an aluminum halide such as aluminum trichloride. For an aluminum oxide barrier, the reactant can comprise an oxygen reactant such as H₂O₂, H₂O or O₃.

For example, for a titanium oxide barrier the precursor can comprise a titanium alkylamine such as tetrakis(dimethylamino) titanium, a titanium halide such as Titanium (IV) chloride, or a titanium alkoxide such as titanium (IV) isopropoxide. For a titanium oxide barrier, the reactant can comprise an oxygen reactant such as O₃, H₂O₂, or O₂.

For example, for a strontium titanate barrier, a cycle can comprise a strontium precursor pulse that comprises exposing the substrate to a strontium precursor, a titanium precursor pulse that comprises exposing the substrate to a titanium precursor, and an oxygen reactant pulse that comprises exposing the substrate to an oxygen reactant. Suitable strontium precursors include strontium pi complexes comprising one or more alkyl-substituted cyclopentadienyl ligands such as bis (1,2,4-tert-butyl cyclopentadienyl) strontium. Suitable titanium precursors include titanium halides such as titanium tetrachloride. Suitable oxygen reactants include H₂O, O₂, and O₃.

For example, for an aluminum nitride barrier, a cycle can comprise an aluminum precursor pulse that comprises exposing the substrate to an aluminum precursor, and a nitrogen reactant pulse that comprises exposing the substrate to a nitrogen reactant. Suitable aluminum precursors include aluminum alkyls such as trimethylaluminium. Suitable nitrogen reactants include ammonia.

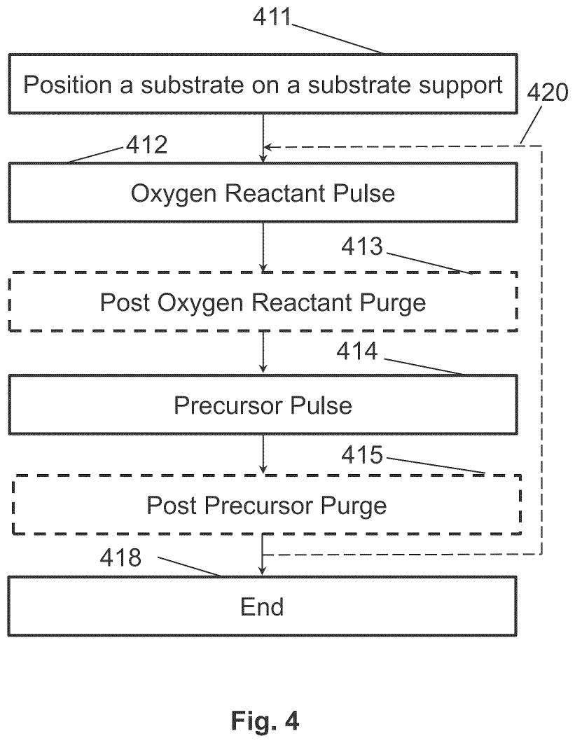

FIG. 4 schematically shows a process flow of an embodiment of a method for forming a barrier layer or for forming a high-k dielectric as described herein. The method comprises a step 411 of positioning a substrate on a substrate support. Then, the method comprises executing 412 a reactant pulse. The reactant pulse comprises exposing the substrate to a reactant, such as an oxygen reactant or a nitrogen reactant. Any suitable reactant as described herein can be used during the reactant pulse. Optionally, a post reactant purge 413 is then carried out. The post oxygen reactant purge 413 comprises exposing the substrate to an oxygen reactant. Then, the method comprises executing 414 a precursor pulse. The precursor pulse comprises a step of exposing the substrate to a precursor. Suitable precursor are described herein. After the precursor pulse 414, the method optionally comprises executing 415 a post precursor purge. The oxygen reactant pulse 412, the precursor pulse 4144, and their respective optional purges 413,415 are optionally repeated one or more times to form one or more cycles 420 until a material having a desired thickness has been deposited. After a material having a desired thickness has been deposited, the method ends 418. Of course, one or more of the cycles 420 can optionally comprise further pulses such as one or more further precursor pulses and one or more further reactant pulses. Optionally the further precursor pulses and further reactant pulses can optionally be separated from adjacent pulses by a purge.

In some embodiments, the high-k dielectric can be formed using atomic layer deposition (ALD). For example, the high-k dielectric can comprise hafnium zirconium oxide, and a suitable ALD process can comprise a plurality of cycles, ones from the plurality of cycles comprising one or more hafnium precursor pulses, one or more zirconium precursor pulses, and one or more oxygen reactant pulses.

Suitable hafnium precursors include hafnium alkylamines such as tetrakis(dimethylamido)hafnium, tetrakis(ethylmethylamido)hafnium, and tetrakis(diethylamido)hafnium. Suitable hafnium precursors include hafnium halides such as HfCl₄ and HfBr₄.

Suitable zirconium precursors include zirconium alkylamines such as tetrakis(dimethylamido)zirconium, tetrakis(ethylmethylamido)zirconium, and tetrakis(diethylamido)zirconium. Suitable zirconium precursors include zirconium halides such as ZrCl₄ and ZrBr₄.

Suitable oxygen reactants include H₂O, O₂, O₃, CO, CO₂, N₂O, NO, and NO₂.

In some embodiments, the high-k dielectric comprises oxygen and one or more of hafnium and zirconium. In some embodiments, the high-k dielectric comprises zirconium oxide. In some embodiments, the high-k dielectric comprises hafnium oxide. In some embodiments, the high-k dielectric comprises hafnium, zirconium, and oxygen. For example, the high-k dielectric can comprise hafnium and zirconium in a one-to-one ration. For example, the high-k dielectric can comprise hafnium and zirconium in a two-to-one ration. It shall be understood that the high-k dielectric can comprise a stoichiometric or non-stoichiometric compound, such as a stoichiometric or a non-stoichiometric oxide.

In some embodiments, the high-k dielectric comprises an oxide such as an oxide selected from the list consisting of hafnium oxide (HfO₂), zirconium oxide (ZrO₂), stoichiometric or non-stoichiometric hafnium zirconium oxide as described herein, and strontium titanate (SrTiO₂).

In some embodiments, at least one of the distal contact and the proximal contact comprises a transition metal nitride. Suitable transition metal nitrides include titanium nitride, molybdenum nitride, niobium nitride, and titanium nitride.

In some embodiments, at least one of the distal contact and the proximal contact comprises a post transition metal nitride. Suitable post transition metal nitrides include aluminum nitride and tungsten nitride.

In some embodiments, at least one of the distal contact and the proximal contact comprises a transition metal. Suitable transition metals include cobalt (Co), molybdenum (Mo), ruthenium (Ru), and tungsten (W).

FIG. 5 curves a) and b) show experimental current-voltage characteristics. The horizontal axis is in volts, the vertical axis shows current density in A/cm². In particular, FIG. 5, curve a) shows an experimental current-voltage characteristic of a reference structure not comprising a barrier, i.e. comprising a high-k dielectric sandwiched between two electrodes. The high-k dielectric comprises hafnium zirconium oxide (HZO), and the proximal and distal electrodes comprise titanium nitride.

FIG. 5, curve b) shows an experimental current-voltage characteristic of an embodiment of a structure as disclosed herein. The structure comprises a proximal electron barrier comprising NiO, a high-k dielectric comprising hafnium zirconium oxide, and proximal and distal electrodes comprising titanium nitride. This embodiment of a structure does not comprise a distal barrier, and is therefore asymmetric, and band diagrams of such a structure are shown in FIGS. 2D, 2E, and 2F for various bias conditions. Note that NiO is a p-type semiconductor with a relatively low electron affinity, which forms a barrier with forbidden states around the conduction band edge of the high-k dielectric.

Consistent with the theory discussed in the context of FIGS. 2D, 2E, and 2F, the experimental results of FIG. 5 show that a NiO barrier reduces leakage current by as much as an order of magnitude for 20 cycles NiO under 5 nm hafnium zirconium oxide (HZO), at high bias, when the proximal electrode adjacent to the NiO barrier is positively biased with respect to the distal electrode which is not separated from the high-k dielectric by a barrier. Conversely, when the proximal electrode adjacent to the NiO barrier is negatively biased with respect to the distal electrode, the NiO barrier was found to have no, or at most a negligible, effect on leakage current density.

In the embodiment for which the current-voltage characteristic is shown in FIGS. 5, 3 to 5 nm of hafnium zirconium oxide (HZO) was used as a high-k dielectric, and a distal barrier comprising NiO was used. The hafnium zirconium oxide was non-stoichiometric, having a zirconium content from at least 60 to at most 80 atomic percent. It shall be understood that the zirconium content is expressed as n_{Zr}/(n_{Zr}+n_{Hf}) with nZr being the molar zirconium concentration in the HZO, and nHf being the molar hafnium concentration in the HZO. Molar concentrations can be measured using analytical techniques such as X-ray Diffraction (XRD). No proximal barrier was employed. The nickel oxide can be formed using atomic layer deposition (ALD) with 5 to 30, or 10 to 40 cycles, or 10 to 15 ALD cycles. Advantageously, 10 to 20 ALD cycles of NiO yield good leakage current reduction without noticeable equivalent oxide thickness increase. X-Ray Diffraction (XRD) data indicated that the morphology of the NiO barrier can be described as isolated islands, nanoparticles, or a dusting, on the high-k dielectric. Only at 40 ALD cycles, a closed NiO layer was formed. This notwithstanding, a NiO distal barrier was found to reduce the leakage current by up to an order of magnitude for only 20 ALD cycles of NiO on 5 nm HZO.

The hafnium zirconium oxide can be subjected to an anneal. Anneals can be employed to crystallize the hafnium zirconium oxide. The anneal can take place immediately after HZO formation, i.e. without any intermediate processing steps. Alternatively, the anneal can take place after forming the proximal barrier or after forming the proximal contact. Suitable anneals can employ an inert gas ambient such as a noble such as Ar or He, or a dinitrogen (N₂) ambient. Suitable annealing temperatures include temperatures from at least 300° C. to at most 500° C., e.g. from at least 400° C. to at most 450° C., e.g. 420° C. Suitable annealing times include from at least 10 minutes to at most 30 minutes, e.g. 20 minutes. Advantageously the crystallization temperature of 5 nm thick HZO was found to be reduced by 10° C. when a distal barrier of 10 ALD cycles of NiO was used, while the dielectric constant (k-value) of HZO was advantageously boosted by a moderate amount. From in depth analysis of leakage current characteristics it can be ascertained that a NiO interface layer is indeed acting as an electron barrier, causing the mitigation of electron emission from the HZO traps, i.e. reducing Poole-Frenkel emission. This is particularly evident in samples comprising 3 nm thick HZO, which are strongly dominated by trap emission leakage mechanism.

Further described herein is a system that comprises a reaction chamber, a precursor source, a reactant source, and a controller. The system is constructed and arranged for executing a method as described herein.

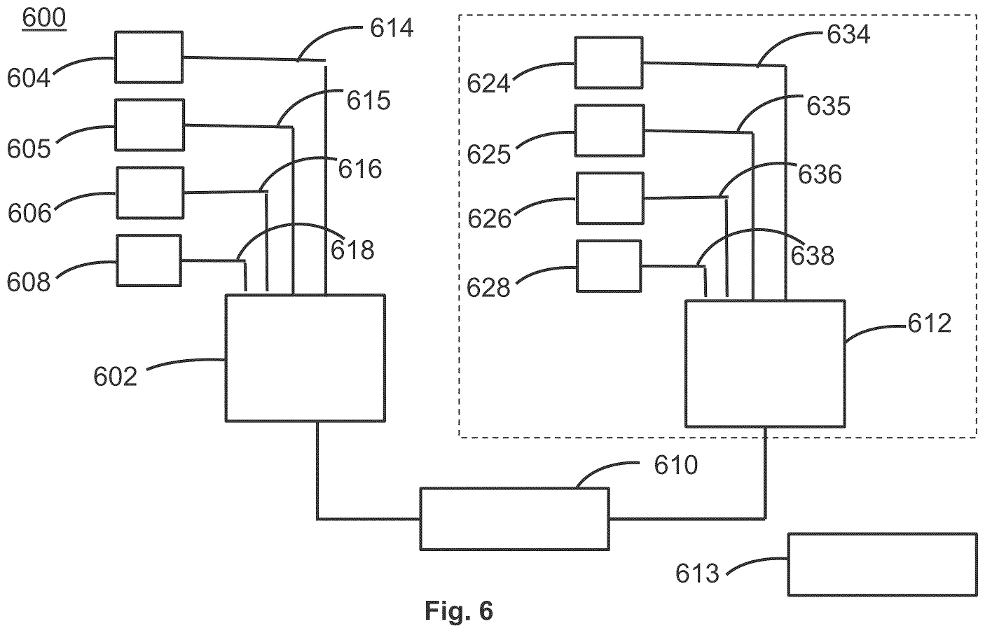

FIG. 6 illustrates a system 600 in accordance with exemplary embodiments of the disclosure. The system 600 can be configured to perform a method as described herein and/or form a structure or device portion as described herein.

In the illustrated example, the system 600 includes a high-k dielectric reaction chamber 602, a first high-k dielectric metal precursor vessel 604, a second high-k dielectric metal precursor vessel 606, a reactant vessel 608, an exhaust 610, and a controller 613. In some embodiments, the system further comprises one or more dopant precursor vessels (not shown). The first high-k dielectric metal precursor vessel 604 can, in some embodiments, comprise a metal precursor such as a hafnium precursor. The second high-k dielectric metal precursor vessel 606 can, in some embodiments, comprise a metal precursor such as a zirconium precursor. The reactant vessel 608 can comprise a reactant such as an oxygen reactant such as O₂.

In some embodiments, the system 600 includes an optional second set of one or more barrier reaction chambers 612, which be constructed and arranged for forming one or more of a proximal barrier and a distal barrier. The one or more barrier reaction chambers can be operationally coupled to a first barrier metal precursor vessel 624, an optional second barrier metal precursor vessel 626, and a barrier reactant vessel 628. Suitable barrier reactants include oxygen reactants and nitrogen reactants as disclosed herein. In some embodiments, the high-k dielectric reaction chamber 602 can be constructed and arranged for forming a ternary metal oxide such as hafnium zirconium oxide, and the barrier reaction chamber can be constructed and arranged for forming a metal nitride such as aluminum nitride.

One or more of the high-k dielectric reaction chamber 602 and the barrier reaction chamber 612 can include an ALD reaction chamber.

One or more of the first high-k dielectric precursor vessel 604 and the barrier precursor vessel 624 can include a container and one or more precursors as described herein-alone or mixed with one or more carrier (e.g., noble) gases. The One or more of the second high-k dielectric precursor vessel 606 and the second barrier precursor vessel 626 can include a container and one or more metal precursors as described herein—alone or mixed with one or more carrier gases. One or more of the high-k dielectric reactant source 608 and the barrier reactant source 628 can include one or more reactants such as oxygen reactants or nitrogen reactants as described herein.

In some embodiments, the system 600 comprises a single reaction chamber 602, or a set of identical reaction chambers 602. In such embodiments, an oxide high-k dielectric and an oxide barrier can be formed in that one reaction chamber 602.

Although illustrated with eight vessels 604-628, the system 600 can include any suitable number of vessels. The vessels 604-628 can be coupled to one or more reaction chambers 602,612 via lines 614-638, which can each include flow controllers, valves, heaters, and the like. The exhaust 610 can include one or more vacuum pumps. The exhaust is connected to one or more of the reaction chambers 602,612 via lines.

In some embodiments, the high-k dielectric reaction chamber 602 can further be configured for forming at least one of a distal barrier or a proximal barrier that comprises a metal oxide. For example, this can be done when the high-k dielectric comprises hafnium zirconium oxide and when at least one of the proximal barrier and the distal barrier comprises one or more of nickel oxide (NiO), magnesium oxide (MgO), scandium oxide (Sc2O3), lanthanum oxide (La₂O₃), aluminum oxide (Al₂O₃), zirconium oxide (ZrO₂), hafnium oxide (HfO₂), and titanium oxide (TiO₂). Thus, in such embodiments, the high-k dielectric reaction chamber 602 can further be operationally connected to one or more further metal precursor sources, and to one or more oxygen reactant sources. In such embodiments, the optional second set of one or more barrier reaction chambers 612 can be omitted from the system 600.

The controller 613 includes electronic circuitry and software to selectively operate valves, manifolds, heaters, pumps and other components included in the system 600. Such circuitry and components operate to introduce precursors, reactants, and purge gases from the respective vessels 604-628.

The controller 613 can control timing of gas pulse sequences, temperature of the substrates and/or reaction chambers, pressure within the reaction chambers, and various other operations to provide proper operation of the system 600. The controller 613 can include control software to electrically or pneumatically control valves to control flow of precursors, reactants and purge gases into and out of the reaction chambers 602,612. The controller 612 can include modules such as a software or hardware component, e.g., an FPGA or ASIC, which performs certain tasks. A module can advantageously be configured to reside on the addressable storage medium of the control system and be configured to execute one or more processes as described herein.

Other configurations of the system 600 are possible, including different numbers and kinds of precursor and oxygen reactant sources and optionally further including purge gas vessels. Further, it will be appreciated that there are many arrangements of valves, conduits, precursor vessels, and purge gas vessels that may be used to accomplish the goal of selectively feeding gases into the reaction chambers 602,612. Further, as a schematic representation of a system, many components have been omitted for simplicity of illustration, and such components may include, for example, various valves, manifolds, purifiers, heaters, containers, vents, and/or bypasses.

During operation of the system 600, substrates, such as semiconductor wafers (not illustrated), are transferred from, e.g., a substrate handling system to the reaction chambers 602, 612. Once the substrate(s) are transferred to the reaction chamber 602,612, one or more gases from the vessels 604-628, such as precursors, reactants, carrier gases, and/or purge gases, are introduced into the reaction chambers 602,612.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A structure comprising a proximal contact, a proximal barrier, a high-k dielectric, and a distal contact;
the proximal contact being adjacent to the proximal barrier; and
the proximal barrier being positioned between the proximal contact and the high-k dielectric, and the high-k dielectric being positioned between the proximal barrier and the distal contact,
wherein the proximal barrier is constructed and arranged to inhibit Poole-Frenkel emission from the high-k dielectric when a first electric field is applied between the proximal contact and a distal contact in a first electric field direction.

2. The structure according to claim 1 further comprising a distal barrier, the distal barrier being positioned between the high-k dielectric and the distal contact, the distal barrier being constructed and arranged to inhibit Poole-Frenkel emission from the high-k dielectric when a second electric field is applied between the proximal contact and the distal contact in a second electric field direction, the second electric field direction being opposite to the first electric field direction.

3. The structure according to claim 2, wherein at least one of the distal barrier and the proximal barrier comprises a plurality of nanoparticles.

4. The structure according to claim 2, wherein the high-k dielectric has a high-k dielectric band gap, wherein the proximal barrier has a proximal barrier band gap, and optionally wherein the distal barrier has a distal barrier band gap.

5. The structure according to claim 4, wherein at least one of the proximal barrier band gap and the distal barrier band gap is smaller than the high-k dielectric band gap.

6. The structure according to claim 5, wherein the distal barrier band gap and the high-k dielectric band gap define a distal valence band offset, optionally wherein the proximal barrier band gap and the high-k dielectric band gap define a proximal valence band offset.

7. The structure according to claim 6, wherein at least one of the proximal valence band offset and the distal valence band offset are greater than 0.5 eV.

8. The structure according to claim 6, wherein the distal barrier band gap and the high-k dielectric band gap further define a distal conduction band offset, optionally wherein the proximal barrier band gap and the high-k dielectric band gap further define a proximal conduction band offset; and, wherein the distal valence band offset is bigger than the distal conduction band offset, and/or wherein the proximal valence band offset is bigger than the proximal conduction band offset.

9. The structure according to claim 4, wherein the distal barrier band gap and the high-k dielectric band gap define a distal conduction band offset, optionally wherein the proximal barrier band gap and the high-k dielectric band gap define a proximal conduction band offset.

10. The structure according to claim 9, wherein at least one of the proximal conduction band offset and the distal conduction band offset are greater than 0.5 eV.

11. The structure according to claim 9, wherein the distal barrier band gap and the high-k dielectric band gap further define a distal valence band offset, optionally wherein the proximal barrier band gap and the high-k dielectric band gap further define a proximal valence band offset; and, wherein the distal conduction band offset is bigger than the distal valence band offset, and/or wherein the proximal conduction band offset is bigger than the proximal valence band offset.

12. A method of forming a structure, the method comprising:
providing a substrate to a reaction chamber, the substrate comprising a distal contact;
forming a distal barrier on the distal contact;
forming a high-k dielectric on the distal barrier;
forming a proximal barrier on the high-k dielectric; and,
forming a proximal contact on the proximal barrier.

13. The method according to claim 12, wherein the structure comprises the proximal contact, the proximal barrier, the high-k dielectric, and the distal contact;
the proximal contact being adjacent to the proximal barrier; and
the proximal barrier being positioned between the proximal contact and the high-k dielectric, and the high-k dielectric being positioned between the proximal barrier and the distal contact,
wherein the proximal barrier is constructed and arranged to inhibit Poole-Frenkel emission from the high-k dielectric when a first electric field is applied between the proximal contact and a distal contact in a first electric field direction.

14. The method according to claim 12, wherein forming at least one of the distal barrier and the proximal barrier comprises executing a cyclical deposition process, the cyclical deposition process comprising a plurality of deposition cycles, ones from the plurality of deposition cycles comprising a precursor pulse and a reactant pulse, the precursor pulse comprising contacting the substrate with a precursor, and the reactant pulse comprising contacting the substrate with a reactant.

15. The structure according to claim 2, wherein at least one of the distal barrier and the proximal barrier comprises one or more of nickel oxide, aluminum nitride, magnesium oxide, scandium oxide, lanthanum oxide, aluminum oxide, zirconium oxide, hafnium oxide, strontium titanium oxide, and titanium oxide.

16. The structure according to claim 1, wherein the high-k dielectric comprises hafnium, zirconium, and oxygen.

17. The structure according to claim 1, wherein at least one of the distal contact and the proximal contact comprises a transition metal nitride.

18. The structure according to claim 2, wherein at least one of the proximal barrier and the distal barrier does not substantially contribute to an equivalent oxide thickness of a capacitor formed by the high-k dielectric, the distal contact, the proximal contact, and one or more of the proximal barrier and the distal barrier.

19. A system comprising a reaction chamber, a precursor source, a reactant source, and a controller, wherein the system is constructed and arranged for executing a method according to claim 12.
